(19) United States
(12) Patent Application Publication
(10) Pub. No.: US 2015/0230346 A1
(43) Pub. Date: Aug. 13, 2015

(54) MASK FOR LOADING BALL, BALL LOADING APPARATUS AND METHOD FOR MANUFACTURING PRINTED WRING BOARD USING MASK

(71) Applicant: IBIDEN CO., LTD., Ogaki (JP)

(72) Inventors: Katsuhiko TANNO, Ogaki (JP); Yusuke KAWAMURA, Ogaki (JP); Seito ADACHI, Ogaki (JP)

(73) Assignee: IBIDEN CO., LTD., Ogaki (JP)

(21) Appl. No.: 14/621,828

(22) Filed: Feb. 13, 2015

(30) Foreign Application Priority Data
Feb. 13, 2014 (JP) 2014-025296

(51) Int. Cl. H05K 3/34; B32B 38/10; H05K 3/00; B32B 37/24; B23K 1/00; B23K 3/06

(52) U.S. Cl. CPC H05K 3/3452; B23K 1/0016; B23K 3/0623; H05K 3/0058; H05K 3/0079; H05K 3/0076; B32B 37/24; B32B 38/10; H05K 2203/06; H05K 2203/041; H05K 2203/043; B32B 2037/243; B32B 2307/202; B32B 2307/206; B32B 2457/08

(57) ABSTRACT

A method for manufacturing a printed wiring board includes clamping a mask device at clamping portioned formed in the mask device with a movable clamp device to apply tensile force to the mask device, positioning the mask device over a printed wiring board having connection pads, applying the tensile force to the mask device through the clamping portions such that a mask of the mask device undergoes elastic deformation and positions of opening portions in the mask are vertically aligned relative to positions of the connection pads of the printed wiring board, and loading solder balls through the opening portions in the mask onto the connection pads of the printed wiring board, respectively.

### CROSS-REFERENCE TO RELATED APPLICATIONS

The present application is based upon and claims the benefit of priority to Japanese Patent Application No. 2014-025296, filed Feb. 13, 2014, the entire contents of which are incorporated herein by reference.

### BACKGROUND OF THE INVENTION

1. Field of the Invention

The present invention relates to a ball loading mask for loading a solder ball, which is subsequently formed into a solder bump, on each connection pad positioned in a connection-pad region of a printed wiring board, and to a ball loading apparatus.

2. Description of Background Art

JP2006-074001A describes a ball loading apparatus for loading a solder ball, which is subsequently formed into a solder bump, on each connection pad in the connection-pad region of a printed wiring board. The apparatus of JP2006-074001A loads a solder ball having a diameter of less than 200 μm on each connection pad, and the mechanism described in JP2006-074001A includes the following: a tubular member which is positioned above a ball loading mask and collects solder balls by suctioning air through an opening portion in a location directly under the opening portion; and a transfer member which transfers solder balls collected on the ball loading mask by horizontally moving the tubular member so that solder balls are each dropped on a connection pad of a printed wiring board through the opening of the ball loading mask.

JP2010-050268A describes a combination mask for loading balls which has multiple openings corresponding to multiple connection pads of a printed wiring board. JP2010-050268A proposes to enhance planar accuracy of the metal mask, and the periphery of the metal mask is attached to a hollow frame with a stretchable sheet disposed in between so that each side of the metal mask receives the same level of tensile force, while a protruding member provided on each corner of the metal mask exerts tensile force in diagonally outward directions.

The entire contents of these publications are incorporated herein by reference.

### SUMMARY OF THE INVENTION

According to one aspect of the present invention, a method for manufacturing a printed wiring board includes clamping a mask device at clamping portioned formed in the mask device with a movable clamp device which applies tensile force to the mask device, positioning the mask device over a printed wiring board having connection pads, applying the tensile force to the mask device through the clamping portions such that a mask of the mask device undergoes elastic deformation and positions of opening portions in the mask are vertically aligned relative to positions of the connection pads of the printed wiring board, and loading solder balls through the opening portions in the mask onto the connection pads of the printed wiring board, respectively.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 shows a ball loading apparatus according to an embodiment of the present invention and includes FIG. 1(A) showing a front view of the ball loading apparatus, and FIG. 1(B) showing a side view of the ball loading apparatus;

FIG. 2 shows operations of the ball loading apparatus according to the embodiment and includes FIG. 2(A) illustrating a step for aligning a ball loading mask, and FIG. 2(B) illustrating a step for supplying solder balls onto the ball loading mask;

FIG. 3 shows operations of the ball loading apparatus according to the embodiment and includes FIG. 3(A) illustrating a step for collecting solder balls on the ball loading mask, and FIG. 3(B) illustrating a step for transferring solder balls on a printed wiring board;

FIG. 4 shows operations of the ball loading apparatus according to the embodiment and includes FIG. 4(A) illustrating a step for removing excess solder balls on a region where openings of the ball loading mask are present, and FIG. 4(B) illustrating a step for removing excess solder balls from a region where no opening of the ball loading mask is present;

FIG. 5(A) is a plan view showing a ball loading mask according to another embodiment of the present invention;

FIG. 5(B) is a view schematically showing how the ball loading mask is deformed by the mask deformation mechanism provided in the ball loading apparatus of the embodiment;

FIG. 6(A) is a plan view showing an example where opening intervals of the ball loading mask are wider than the intervals of connection pads of a printed wiring board;

FIG. 6(B) is a plan view showing another example where opening intervals of the ball loading mask are wider than the intervals of connection pads of a printed wiring board;

FIG. 7(A) is a stress-strain diagram showing the relationship of strain to the stress exerted on a nickel metal mask provided in the ball loading mask according to an embodiment of the present invention;

FIG. 7(B) is a stress-strain diagram showing the relationship of strain to the stress exerted on the buffer area of a polyester woven cloth provided in the ball loading mask according to the embodiment; and

FIG. 8(A)˜8(E) show various methods for exerting tensile force onto a metal mask.

### DETAILED DESCRIPTION OF THE EMBODIMENTS

The embodiments will now be described with reference to the accompanying drawings, wherein like reference numerals designate corresponding or identical elements throughout the various drawings.

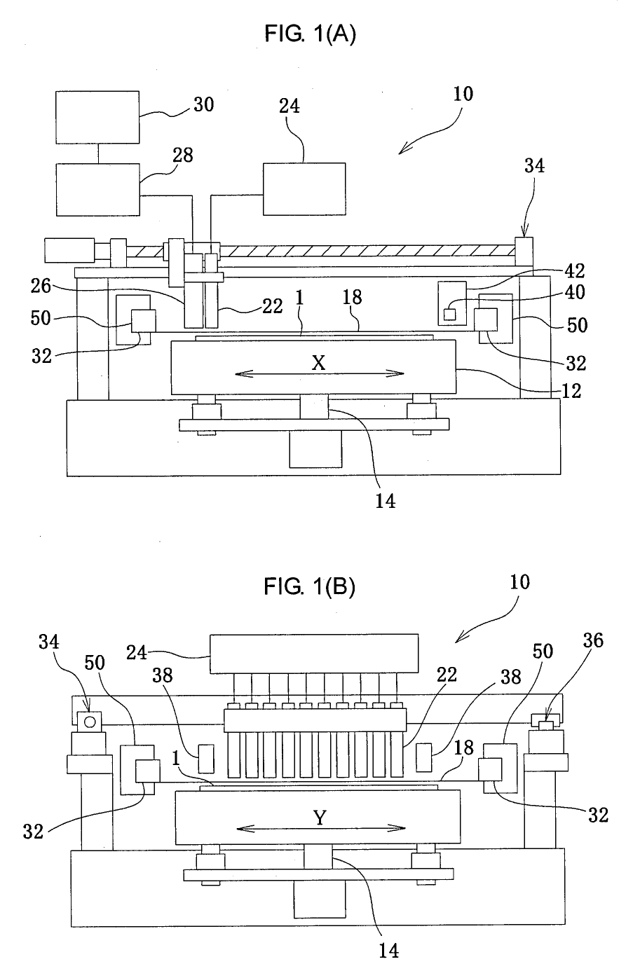

First, ball loading apparatus 10 is described according to an embodiment of the present invention. FIGS. 1(A) and 1(B) show ball loading apparatus 10 according to an embodiment of the present invention.

Ball loading apparatus 10 of the present embodiment is provided with the following: XYθ suction table 12 to align and hold multilayer printed wiring board 1; table lifting/moving mechanism 14 to lift and move XYθ suction table 12; ball loading mask 18 having later-described multiple openings 16 that correspond to later-described multiple connection pads 3 of multilayer printed wiring board 1; later-described loading tubes 22 to guide solder balls 20 traveling on ball loading mask 18; suction box 24 to give negative pressure to loading tubes 22; ball removal tubes 26 to collect excess solder balls 20; suction box 28 to give negative pressure to ball removal tubes 26; and suction ball-removal device 30 to keep collected solder balls 20.

Ball loading apparatus 10 of the present embodiment further includes: mask clamp 32 to clamp ball loading mask 18; direction-X moving mechanism 34 to move loading tubes 22 and ball removal tubes 26 in direction X; support guide 36 to support direction-X moving mechanism 34; alignment camera 38 to take images of multilayer printed wiring board 1; remaining-ball detection sensor 40 to detect the amount of remaining solder balls 20 under loading tubes 22; and solder-ball supply device 42 to supply solder balls to loading tubes 22 based on the amount of remaining balls detected by remaining-ball detection sensor 40. Ball loading apparatus 10 shown in the accompanying drawings is provided only with direction-X moving mechanism 34 as a mechanism for moving loading tubes 22 and ball removal tubes 26 in direction X. However, it is also an option to have a direction-Y moving mechanism.

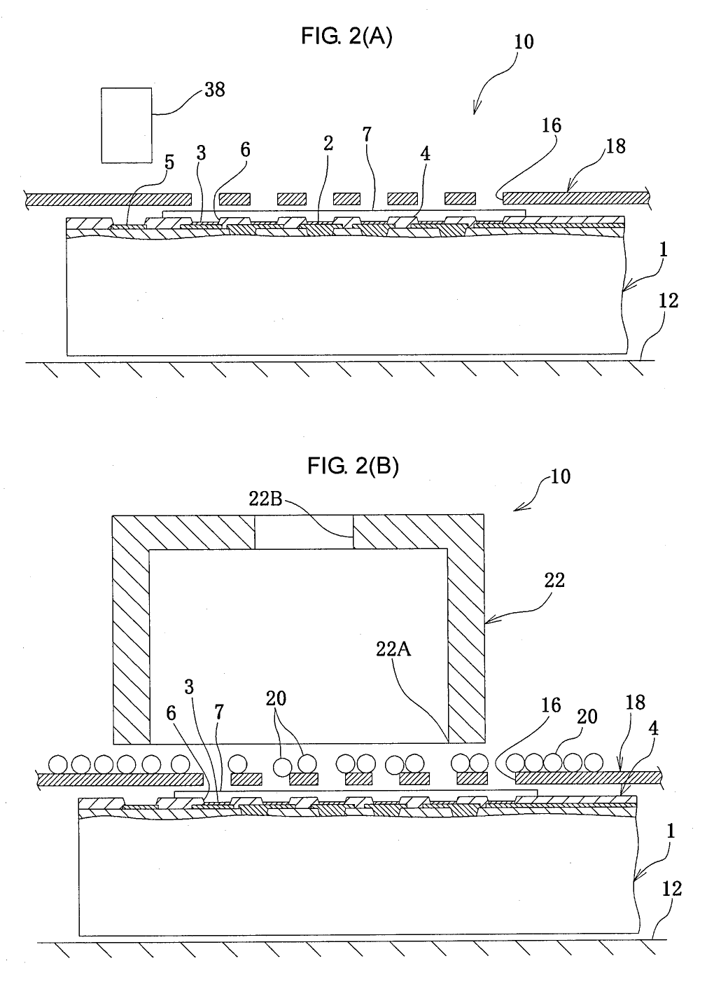

In a loading tube 22, lower opening portion (22A) (see FIG. 2(B)) is formed in a rectangular shape. Thus, solder balls 20 collected in an approximately rectangular shape are efficiently loaded on multiple connection pads 3 formed in an approximately rectangular connection-pad region of an individual multilayer printed wiring board of multipiece multilayer printed wiring board 1. The above multipiece multilayer printed wiring board 1, multiple loading tubes 22 and ball removal tubes 26 of ball loading apparatus 10 are arranged in direction Y, corresponding to individual connection-pad regions. Here, one loading tube 22 is arranged for one connection-pad region, but loading tube 22 may be formed to have a size large enough to cover multiple connection-pad regions. In addition, loading tubes 22 and ball removal tubes 26 are arranged in direction Y only for the sake of convenience. If there is another mechanism provided for moving loading tubes 22 and ball removal tubes 26 in direction Y, loading tubes 22 and ball removal tubes 26 may be arranged in direction X.

XYθ suction table 12 aligns, suctions, holds and adjusts multilayer printed wiring board 1 on which solder balls are to be loaded. Alignment camera 38 detects later-described alignment marks 5 of multilayer printed wiring board 1 positioned on XYθ suction table 12. Based on the detected positions, positions of multilayer printed wiring board 1 and ball loading mask 18 are adjusted. Remaining-ball detection sensor 40 optically detects the remaining amount of solder balls.

Steps for loading solder balls 20 by ball loading apparatus 10 are described with reference to FIG. 2˜4. As shown in FIG. 2(A), solder-resist layer 4 is formed on the outermost conductive layer 2 of multilayer printed wiring board 1, and alignment marks 5 made of part of conductive layer 2 as well as connection pads 3 formed on conductive layer 2 are exposed in openings 6 of solder-resist layer 4. Flux 7 is printed on solder-resist layer 4 to cover connection pads 3. Flux 7 holds solder balls 20 in their loaded positions on connection pads 3 and helps solder bumps to be connected to connection pads 3 when bumps are formed from solder balls 20 during a reflow process.

(1) Positional Recognition and Positional Adjustment of Multilayer Printed Wiring Board

As shown in FIG. 2(A), multipiece multilayer printed wiring board 1 is loaded on XYθ suction table 12, and alignment marks 5 of multilayer printed wiring board 1 are recognized by alignment camera 38 so that the position of multilayer printed wiring board 1 relative to that of ball loading mask 18 is adjusted by XYθ suction table 12. Namely, first, the position of multilayer printed wiring board 1 is adjusted to make an approximate alignment of vertical positions of multiple openings 16 of ball loading mask 18 and multiple connection pads 3 of multilayer printed wiring board 1. Then, ball loading mask 18 undergoes elastic deformation as described later. Accordingly, multiple openings 16 of ball loading mask 18 are vertically aligned with their respective multiple connection pads 3 of multilayer printed wiring board 1.

(2) Supplying Solder Balls

As shown in FIG. 2(B), a fixed amount of solder balls 20 is supplied from solder ball supply device 42 to the region of loading tubes 22 on ball loading mask 18. Here, solder balls 20 may also be supplied in advance inside loading tubes 22.

(3) Loading Solder Balls

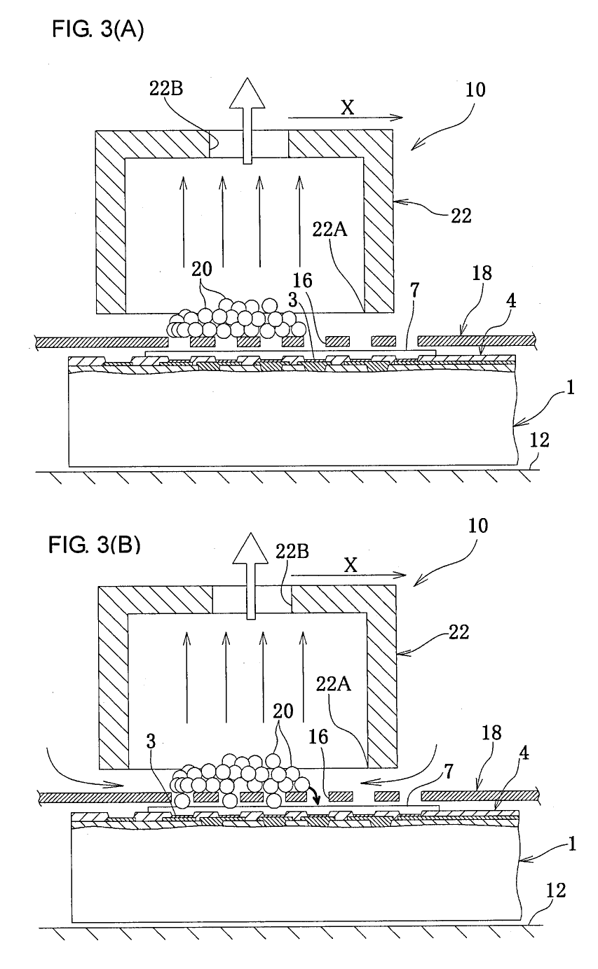

As shown in FIG. 3(A), loading tube 22 is positioned over ball loading mask 18 to have a predetermined clearance (for example, 0.5˜4 times the ball diameter) with ball loading mask 18. Then, air is suctioned through suction portion (22B) of loading tube 22 with an air flow rate of 5 msec˜35 msec, for example, passing through the gap between loading tube 22 and multilayer printed wiring board 1 so that solder balls 20 are collected on ball loading mask 18 positioned directly under opening portion (24A) of loading tube 22.

Next, as shown in FIG. 3(B), loading tubes 22 aligned along axis Y of multilayer printed wiring board 1 are moved horizontally in direction X by direction-X moving mechanism 34 so that solder balls collected on ball loading mask 18 are transferred as loading tubes 22 move. Then, solder balls 20 are loaded when they are dropped on flux 7 directly on connection pads 3 of multilayer printed wiring board 1 through openings 16 of ball loading mask 18. By so doing, solder balls 20 are arrayed one by one on all the connection pads 3 of multilayer printed wiring board 1.

(4) Removing Solder Balls to Mask

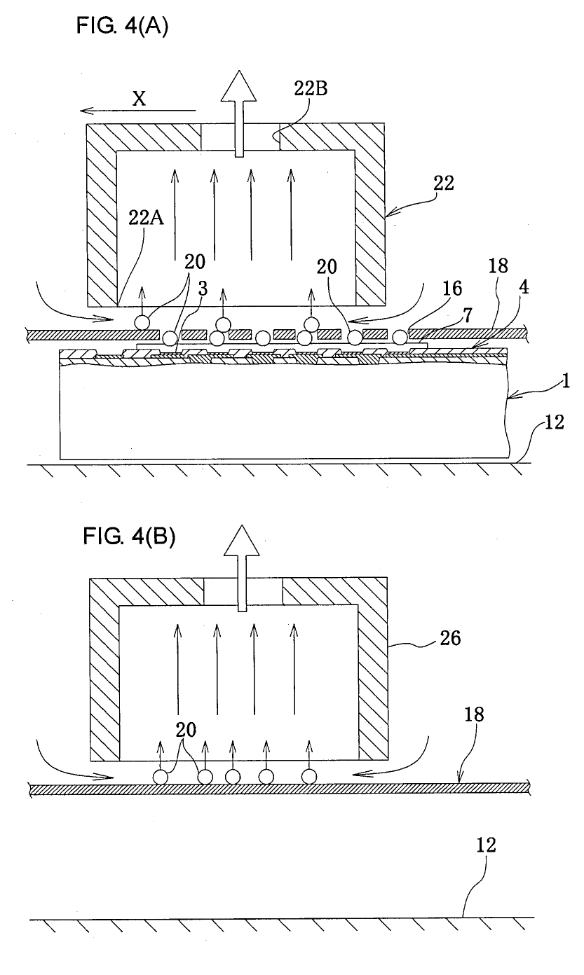

As shown in FIG. 4(B), while part of solder balls 20 are suctioned and removed by loading tubes 22, excess solder balls 20 are guided to a region of ball loading mask 18 where no opening 16 is formed. Then, those guided excess solder balls are suctioned and removed through ball removal tube 26.

(5) Unloading Multilayer Printed Wiring Board

Multilayer printed wiring board 1 with loaded solder balls 20 is removed from XYθ suction table 12 and unloaded from ball loading apparatus 10. Heat is applied on the unloaded multilayer printed wiring board 1 for a predetermined duration at a predetermined temperature so that solder balls 20 are reflowed to form solder bumps on connection pads 3.

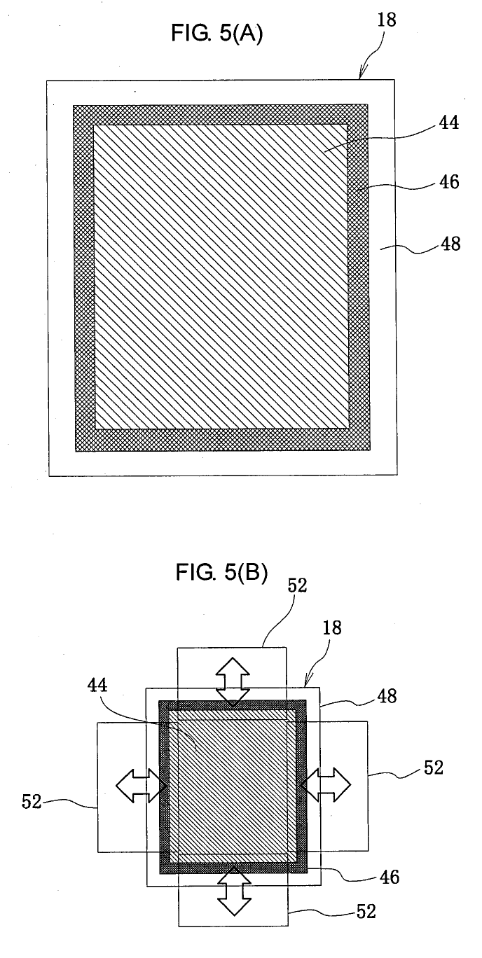

Next, a description is provided for ball loading mask 18 used in ball loading apparatus 10 according to an embodiment of the present invention. FIG. 5(A) is a plan view of a ball loading mask according to an embodiment of the present invention, and FIG. 5(B) is a view schematically illustrating how the ball loading mask is deformed by the mask deformation mechanism of the ball loading apparatus.

As shown in FIG. 5(A), ball loading mask 18 of the present embodiment is provided with rectangular metal mask 44 having aforementioned openings 16, buffer area 46 made of a net to support the periphery of metal mask 44, and mask frame 48 to support the periphery of buffer area 46. Metal mask 44 is made of thin metal foil, for example, a 500×600 mm nickel foil sheet with a thickness of 47 μm, and has a Young's modulus of 141.6 GPa (69.2 GPa in a connection-pad region with multiple openings 16 formed therein). Buffer area 46 is made of stretchable woven cloth made of polyester yarn, for example, and has a Young's modulus of 0.8 GPa.

Mask clamp 32 provided in ball loading apparatus 10 has fixed clamps to horizontally fix and hold mask frame 48 of ball loading mask 18 as shown in FIGS. 1(A) and 1(B) as well as multiple movable clamps 52 to be horizontally moved by mask deformation mechanism 50 as shown in FIG. 5(B), although omitted in FIGS. 1(A) and 1(B). Those movable clamps 52 clamp multiple peripheral portions of metal mask 44 or multiple peripheral portions of buffer area 46 in ball loading mask 18 so that tensile force of metal mask 44 is changed directly or indirectly by way of buffer area 46.

The same as direction-X moving mechanism 34, mask deformation mechanism 50 is structured to linearly move each movable clamp 52 by using a screw moving mechanism, designed to move a nut when a screw attached to the nut rotates while being driven by a motor; or by using a cam moving mechanism, designed to move a cam follower when the cam rotates while being driven by a motor.

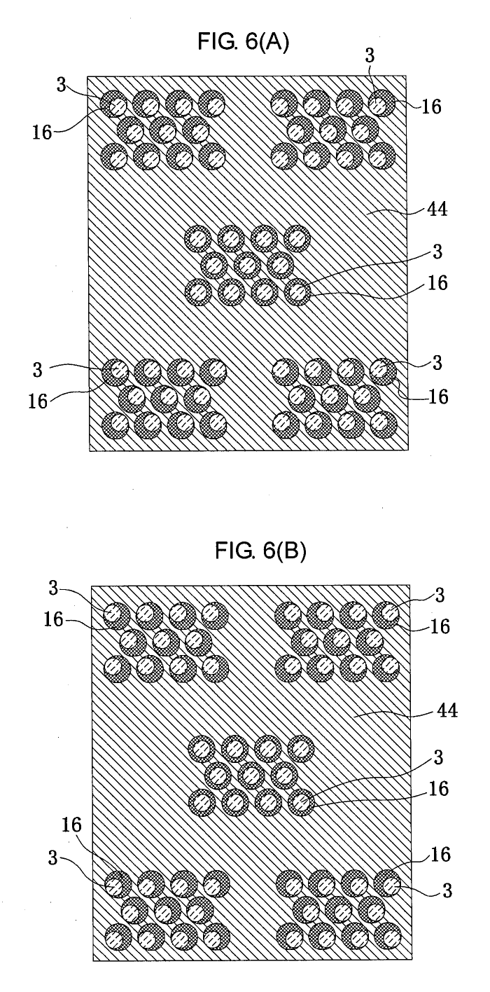

FIG. 6(A) is a plan view showing an example where the opening intervals of a ball loading mask are wider than the intervals of connection pads of a printed wiring board, and FIG. 6(B) is a plan view showing another example where the opening intervals of a ball loading mask are wider than the intervals of connection pads of a printed wiring board. Multipiece multilayer printed wiring board 1 may vary in size by approximately 60 μm. Since positions of openings of a conventional metal mask are fixed, when connection pads 3 in the central connection-pad region of multipiece multilayer printed wiring board 1 are aligned with central openings of metal mask, the aforementioned size variation causes positions of connection pads 3 in the peripheral connection-pad regions of multilayer printed wiring board 1 to deviate from the centers of openings of metal mask as shown in FIGS. 6(A) and 6(B).

When the deviation of a ball loading position is significantly greater than the radius of connection pad 3, solder ball 20 may not make contact with connection pad 3 during a reflow process. As a result, problems may arise after the reflow; for example, a solder bump may fail to be connected to connection pad 3 or a solder bump may be integrated with an adjacent solder bump.

To solve the above-mentioned problems, when peripheral clamp portions are held by movable clamps 52 so that tensile force is changed in ball loading mask 18 of the present embodiment, metal mask 44 undergoes elastic deformation by stretching or contracting so as to change the positions of multiple openings 16 relative to positions of multiple connection pads 3 of multilayer printed wiring board 1.

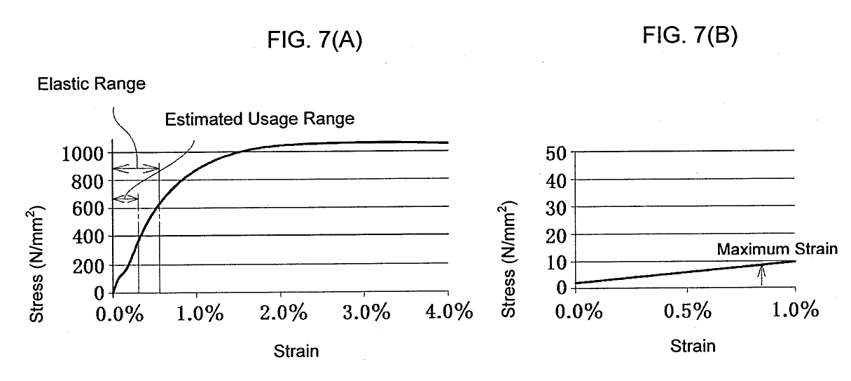

FIG. 7(A) is a stress-strain diagram showing the relationship of strain to the stress exerted on a nickel metal mask in the ball loading mask according to an embodiment of the present invention. FIG. 7(B) is a stress-strain diagram showing the relationship of strain to the stress exerted on a polyester woven cloth in the buffer area of the ball loading mask according to an embodiment of the present invention.

To cause a strain of 60 μm in nickel metal mask 44 so as to correspond to a size variation of 60 μm in multipiece multilayer printed wiring board 1, tensile force of approximately 50 N/m² is applied. To maintain its high planar accuracy, metal mask 44 is fixed to mask frame 48 by an initial tensile force of approximately 100 N/m² exerted on metal mask 44 through buffer area 46. Therefore, even when tensile force of 50 N/m² is added or reduced, metal mask 44 is capable of stretching or contracting within the elastic range as shown in FIG. 7(A).

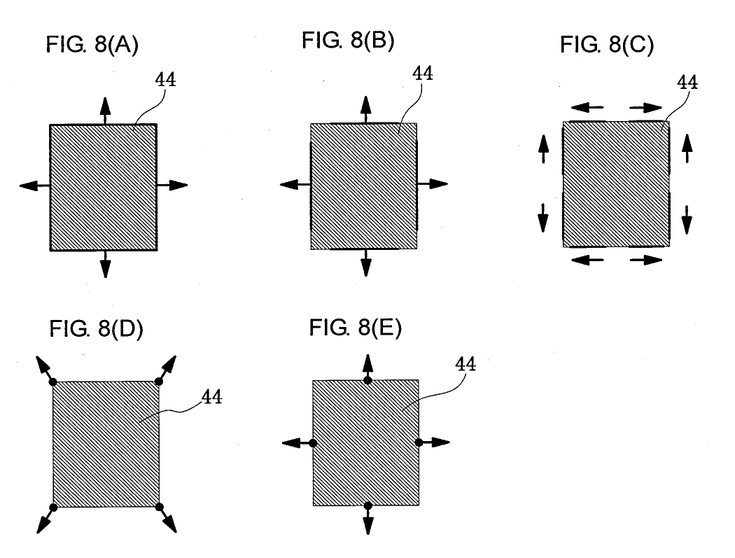

FIG. 8(A)˜8(E) are views illustrating methods for exerting tensile force onto the metal mask using movable clamps 52. Bold lines and black dots are points on which tensile force is exerted, and arrows indicate directions of tensile force. FIG. 8(A) is a method for stretching each entire peripheral side of metal mask 44 by way of buffer area 46; FIG. 8(B) is a method for stretching part of each peripheral side of metal mask 44; FIG. 8(C) is a method for stretching each peripheral side of metal mask 44 from the center of each side in opposite directions; FIG. 8(D) is a method for stretching each peripheral corner of metal mask 44; and FIG. 8(E) is a method for pulling the center of each peripheral side of metal mask 44.

In examples shown in FIG. 8(A)˜8(E), simulations using a normal finite element method were conducted: tensile force was exerted on the periphery of metal mask 44, strain in planar directions (directions (X, Y)) was measured at 0.8 mm intervals, and the results were converted into numerical values. When variations in strain in metal mask 44 were calculated, it was 0.0000% in the method of FIG. 8(A), 0.0004% in the method of FIG. 8(B), 0.0027% in the method of FIG. 8(C), 0.0028% in the method of FIG. 8(D), and 0.0040% in the method of FIG. 8(E). Therefore, to exert tensile force on the periphery of metal mask 44, methods shown in FIG. 8(A)˜8(D) with a strain variation of 0.0028% or lower are preferred, and methods shown in FIGS. 8(A) and 8(B) with a strain variation of 0.0004% or lower are more preferred.

The strain in a thickness direction (direction Z) of metal mask 44 obtained by a simulation conducted in the same manner as above was approximately 0.05% at maximum. That is equivalent to a deformation of 0.01 μm, and the value is sufficiently small compared with a finish tolerance of 2 μm of metal mask 44 and thus can be ignored.

Furthermore, the maximum strain in buffer area 46 made of polyester woven cloth was approximately 0.87% in direction X by a simulation conducted in the same manner as above. Deformation of buffer area 46 is controlled to be within the elastic range shown in FIG. 7(B). According to the simulation, when tensile force was exerted on metal mask 44 by way of buffer area 46, it was confirmed that tensile force was uniformly exerted on metal mask 44 without causing strain.

The ball loading mask and ball loading apparatus according to the embodiments of the present invention are capable of making adjustment to positional variations of connection pads 3 in multipiece multilayer printed wiring board 1 using fewer ball loading masks 18 than in a conventional method. Accordingly, the manufacturing cost of printed wiring boards is reduced.

So far, embodiments of the present invention have been described with reference to the accompanying drawings. However, the present invention is not limited to the above examples, and various modifications are possible within a scope of patent claims. For example, various examples for stretching a metal mask are shown in FIG. 8, but those are not the only options for the mask deformation mechanism in the ball loading apparatus of the embodiment. For example, movable clamps may also be moved in directions opposite those indicated by arrows in the drawings so that the initial tensile force is reduced. Also, ball loading apparatus 10 of the embodiment moves loading tubes 22 and ball removal tubes 26 by direction-X moving mechanism 34 to load solder balls 20 on printed wiring board 1. However, that is not the only option. A ball loading apparatus according to an embodiment of the present invention may use other methods for loading solder balls 20 on printed wiring board 1.

Furthermore, in ball loading mask 18 of the embodiment, mask frame 48 is one integrated frame and movable clamps 52 hold the periphery of the metal mask or the periphery of the buffer area positioned on the inner side of mask frame 48. However, that is not the only option for the ball loading mask of the embodiment. The mask frame may be divided into multiple sections and movable clamps may hold clamp portions provided respectively for those multiple sections of the mask frame.

Yet furthermore, metal mask 44 is supported by mask frame 48 by way of buffer area 46 in ball loading mask 18 of the embodiment. However, the ball loading mask of the embodiment may also be supported directly by a mask frame.

In ball loading mask 18 of the embodiment, buffer area 46 is made of polyester woven cloth and metal mask 44 is made of nickel. However, other materials for the metal mask and buffer area may also be selected appropriately to be used for the ball loading mask of the embodiment.

The ball loading mask and ball loading apparatus according to the embodiments of the present invention are capable of making adjustment to positional variations of connection pads in printed wiring boards using fewer ball loading masks than in a conventional method. Accordingly, the manufacturing cost of printed wiring boards is reduced.

Positions of multiple connection pads in a printed wiring board may vary among printed wiring boards. When the position of a connection pad of a printed wiring board is shifted more than half the size of an electrode from the position of an opening of the mask, a solder ball fails to be loaded on the connection pad during a solder ball loading procedure using a ball loading apparatus. As a result, a solder bump may not be formed properly. A connection pad is more likely than before to undergo positional shifting relative to an opening in a mask since the wiring pitch of printed wiring boards has become finer in recent years. Thus, multiple masks with different opening positions are prepared conventionally, but using multiple masks causes an increase in production cost.

A combination mask may enhance planar accuracy by tensile force exerted on the metal mask. However, in such a combination mask, positions of openings in the mask are not adjustable.

According to an embodiment of the present invention, fewer masks are used to handle varied positions of connection pads in a printed wiring board, and a production cost of a printed wiring board can be reduced.

A mask for loading balls according to one aspect of the present invention has multiple openings corresponding to multiple connection pads of a printed wiring board. Such a mask is characterized in that when clamp portions in the periphery of the ball loading mask are clamped and tensile force is changed, the ball loading mask undergoes elastic deformation to cause positions of the multiple openings to be changed relative to positions of multiple connection pads in the printed wiring board.

In addition, a ball loading apparatus according to another aspect of the present invention loads a solder ball, which later forms a solder bump, on each connection pad in a connection-pad region of a printed wiring board. The ball loading apparatus is provided with the following: multiple mask clamps which clamps clamp portions positioned on the periphery of a ball loading mask having multiple openings that correspond to multiple connection pads of a printed wiring board so that the ball loading mask is aligned and held above the printed wiring board; a solder-ball transfer mechanism which transfers solder balls on the ball loading mask and drops them onto the multiple connection pads of the printed wiring board through the multiple openings; and a mask deformation mechanism which moves the multiple mask clamps to change tensile force in the ball loading mask and to cause elastic deformation in the ball loading mask so that positions of the multiple openings are changed relative to the positions of the multiple connection pads of the printed wiring board.

Obviously, numerous modifications and variations of the present invention are possible in light of the above teachings. It is therefore to be understood that within the scope of the appended claims, the invention may be practiced otherwise than as specifically described herein.

What is claimed is:

1. A method for manufacturing a printed wiring board, comprising:
clamping a mask device at a plurality of clamping portioned formed in the mask device with a movable clamp device configured to apply tensile force to the mask device;
positioning the mask device over a printed wiring board having a plurality of connection pads;
applying the tensile force to the mask device through the clamping portions such that a mask of the mask device undergoes elastic deformation and that positions of opening portions in the mask are vertically aligned relative to positions of the connection pads of the printed wiring board; and
loading a plurality of solder balls through the plurality of opening portions in the mask onto the plurality of connection pads of the printed wiring board, respectively.

2. A method for manufacturing a printed wiring board according to claim 1, wherein the mask device has a mask frame having the plurality of clamp portions in a peripheral portion of the mask frame.

3. A method for manufacturing a printed wiring board according to claim 2, wherein the peripheral portion of the mask frame has a rectangular shape, and the plurality of clamp portions is positioned along opposing sides of the rectangular shape of the peripheral portion of the mask frame.

4. A method for manufacturing a printed wiring board according to claim 2, wherein the mask frame has a buffer portion, and the plurality of clamp portions is formed in the buffer portion of the mask frame.

5. A method for manufacturing a printed wiring board according to claim 3, wherein the mask frame has a buffer portion, and the plurality of clamp portions is formed in the buffer portion of the mask frame.

6. A method for manufacturing a printed wiring board according to claim 2, wherein the mask frame comprises a plurality of divided portions, and the plurality of clamp portions is formed in the plurality of divided portions, respectively.

7. A method for manufacturing a printed wiring board according to claim 3, wherein the mask frame comprises a plurality of divided portions, and the plurality of clamp portions is formed in the plurality of divided portions, respectively.

8. A method for manufacturing a printed wiring board according to claim 2, wherein the plurality of clamp portions is formed on an inner side of the mask frame toward the mask.

9. A method for manufacturing a printed wiring board according to claim 3, wherein the plurality of clamp portions is formed on an inner side of the mask frame toward the mask.

10. A method for manufacturing a printed wiring board according to claim 1, further comprising:
laminating a plurality of insulation layers and a plurality of conductive layers such that the printed wiring board comprising a multilayer printed wiring board is formed;
coating a solder resist layer on a surface of the multilayer printed wiring board; and
forming a plurality of openings in the solder resist layer such that the plurality of connection pads of the printed wiring board is formed.

11. A method for manufacturing a printed wiring board according to claim 1, further comprising:
reflowing the plurality of solder balls loaded on the plurality of connection pads respectively such that a plurality of solder bump is formed on the printed wiring board.

12. A method for manufacturing a printed wiring board according to claim 11, further comprising:
reflowing the plurality of solder balls loaded on the plurality of connection pads respectively such that a plurality of solder bump is formed on the printed wiring board.

13. A method for manufacturing a printed wiring board according to claim 1, wherein the mask of the mask device comprises a metal mask comprising a metal foil.

14. A method for manufacturing a printed wiring board according to claim 1, wherein the mask of the mask device comprises a nickel metal mask comprising a nickel foil.

15. A method for manufacturing a printed wiring board according to claim 2, wherein the mask frame has a buffer portion comprising a net supporting the mask.

16. A method for manufacturing a printed wiring board according to claim 2, wherein the mask frame has a buffer portion comprising a net supporting the mask, and the mask of the mask device comprises a metal mask comprising a metal foil.

17. A method for manufacturing a printed wiring board according to claim 2, wherein the mask frame has a buffer portion comprising a net supporting the mask, the mask of the mask device comprises a metal mask comprising a metal foil, and the plurality of clamp portions is formed in the buffer portion of the mask frame.

18. A method for manufacturing a printed wiring board according to claim 2, wherein the mask frame has a buffer portion comprising a stretchable woven cloth supporting the mask.

19. A method for manufacturing a printed wiring board according to claim 2, wherein the mask frame has a buffer portion comprising a stretchable woven cloth supporting the mask, and the mask of the mask device comprises a metal mask comprising a metal foil.

20. A method for manufacturing a printed wiring board according to claim 2, wherein the mask frame has a buffer portion comprising a stretchable woven cloth supporting the mask, the mask of the mask device comprises a metal mask comprising a metal foil, and the plurality of clamp portions is formed in the buffer portion of the mask frame.
